(19) United States
(12) Patent Application Publication
(10) Pub. No.: US 2026/0238188 A1
(43) Pub. Date: Aug. 13, 2026

(54) RESONATOR ELEMENT AND RESONATOR DEVICE

(71) Applicant: SEIKO EPSON CORPORATION, Tokyo (JP)

(72) Inventors: Kazuyuki Nagata, Minowa-machi (JP); Toshiya Usuda, Ina-shi (JP); Akira Mizuguchi, Minowa-machi (JP)

(21) Appl. No.: 19/536,619

(22) Filed: Feb. 11, 2026

(30) Foreign Application Priority Data
Feb. 13, 2025 (JP) 2025-021360

(51) Int. Cl. H03H 9/19; H03H 9/05; H03H 9/10; H03H 9/17; H03H 9/21; H03H 9/215; H03H 9/24

(52) U.S. Cl. CPC H03H 9/19; H03H 9/0595; H03H 9/1021; H03H 9/17; H03H 9/21; H03H 9/215; H03H 9/24

(57) ABSTRACT

A resonator element includes: a vibration substrate including a support portion, and three or more vibrating arms extending from the support portion along a first direction and arranged side by side along a second direction orthogonal to the first direction; and driving portions each disposed so as to extend over the support portion and the corresponding vibrating arm and configured to expand and contract in the first direction to cause the corresponding vibrating arm to perform flexural vibration in a third direction orthogonal to the first direction and the second direction, and each driving portion is formed of a laminate including a first electrode, a piezoelectric layer, and a second electrode stacked in this order on the corresponding vibrating arm.

The present application is based on, and claims priority from JP Application Serial Number 2025-021360, filed Feb. 13, 2025, the disclosure of which is hereby incorporated by reference herein in its entirety.

### BACKGROUND

### 1. Technical Field

The present disclosure relates to a resonator element and a resonator device.

### 2. Related Art

JP-A-2021-5784 discloses a resonator element including a base portion and three arms connected to the base portion and extending along one direction, in which a silicon substrate is used for the base portion and the three arms, and a stacked structure including a first electrode, a piezoelectric layer, and a second electrode is formed on the base portion and the three arms.

However, the resonator element described in JP-A-2021-5784 needs to be further improved in vibration characteristics such as achieving lower impedance.

### SUMMARY

According to an aspect of the present disclosure, a resonator device includes three or more vibrating arms extending along a first direction, a support portion connected to ends of the three or more vibrating arms, a fixing portion for fixing the support portion to a base portion, and drive portions provided on the three or more vibrating arms and each having a laminate including at least a piezoelectric layer and an electrode, and the laminates are disposed so as to extend from above the three or more vibrating arms to above a part of the support portion.

### BRIEF DESCRIPTION OF THE DRAWINGS

FIG. 1 is a plan view illustrating a schematic structure of a resonator device according to an embodiment.

FIG. 2 is a cross-sectional view taken along line II-II in FIG. 1.

FIG. 3 is a plan view of a resonator element included in the resonator device.

FIG. 4 is a cross-sectional view of a vibrating arm included in the resonator element.

FIG. 5 is a graph illustrating the relationship between L2/L1 and a normalized impedance.

### DESCRIPTION OF EMBODIMENTS

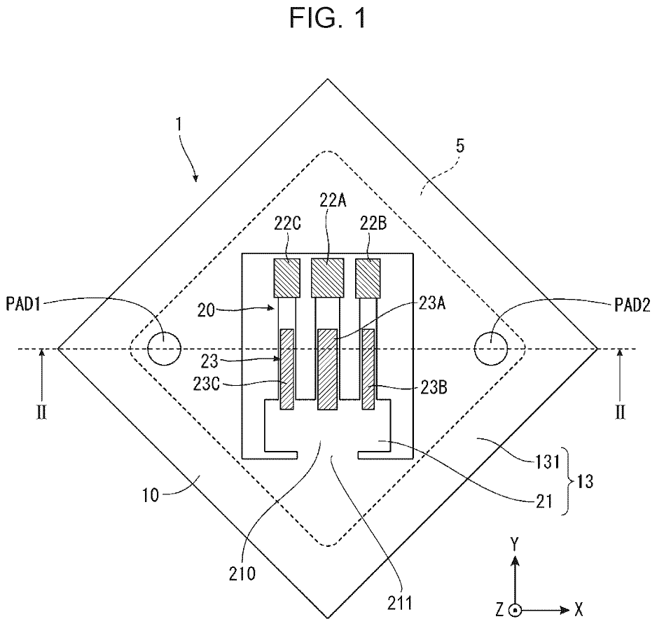

A resonator device 1 according to the present embodiment will be described with reference to FIGS. 1 to 5 by taking a resonator element 20 having three or more vibrating arms 22 as an example.

In the embodiment of the present disclosure, components illustrated in each drawing may be illustrated with different scales of dimensions in order to make the components easy to understand.

For convenience of description, an X-axis, a Y-axis, and a Z-axis are indicated as three axes orthogonal to each other in the following plan views and cross-sectional views. In addition, a direction along the X-axis is also referred to as an X-axis direction, a direction along the Y-axis as a Y-axis direction, and a direction along the Z-axis as a Z-axis direction. Herein, the X-axis direction corresponds to a “second direction”, and the Y-axis direction corresponds to a “first direction”. In addition, an arrow side of each axis is also referred to as a “positive side”, and the side opposite to the arrow is also referred to as a “negative side”. The positive side in the Z-axis direction is also referred to as an “upper side”, and the negative side in the Z-axis direction is also referred to as a “lower side”.

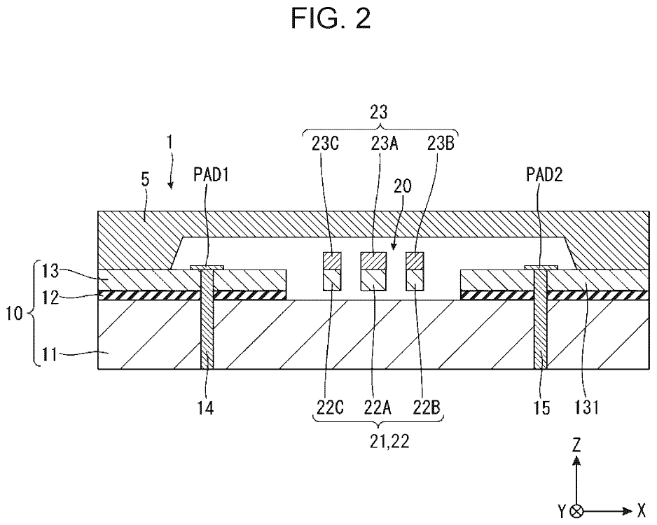

As illustrated in FIGS. 1 and 2, the resonator device 1 includes an SOI (silicon on insulator) substrate 10 in which the resonator element 20 is formed, and a lid portion 5 that hermetically seals the resonator element 20 between the lid portion 5 and the SOI substrate 10. The lid portion 5 is made of single-crystal silicon or the like and has a recessed portion open on the lower side. The lower surface of the lid portion 5 is joined to the upper surface of the SOI substrate 10. As illustrated in FIG. 2, the SOI substrate 10 is a multilayer substrate in which a silicon layer 11 as a handle layer, a BOX (buried oxide) layer 12, and a surface silicon layer 13 as a device layer are stacked in this order from the lower side. For example, each of the silicon layer 11 and the surface silicon layer 13 is made of single-crystal silicon, and the BOX layer 12 is made of a silicon oxide (SiO₂) layer.

In addition, as illustrated in FIG. 1, the surface silicon layer 13 is provided with a vibration substrate 21 that includes the resonator element 20, and a frame-shaped base portion 131 that surrounds the vibration substrate 21. A pair of electrode pads PAD1 and PAD2 are disposed on the upper surface of the base portion 131. In addition, as illustrated in FIG. 2, through electrodes 14 and 15 that extend through the SOI substrate 10 in a thickness direction are formed at positions overlapping the electrode pads PAD1 and PAD2, respectively. The through electrode 14 is electrically coupled to the electrode pad PAD1, and the through electrode 15 is electrically coupled to the electrode pad PAD2. As a result, the electrode pads PAD1 and PAD2 are led out from the lower surface of the resonator device 1 to the outside. Therefore, electrical coupling with an external device such as an oscillation circuit is easy.

In addition, the resonator element 20 has the vibration substrate 21 formed in the surface silicon layer 13. That is, the vibration substrate 21 is formed of a silicon substrate. Since the vibration substrate 21 is formed of a silicon substrate, the vibration substrate 21 can be formed by using a silicon wafer process, and thus the vibration substrate 21 can be easily processed, and the vibration substrate 21 can be formed with high processing accuracy.

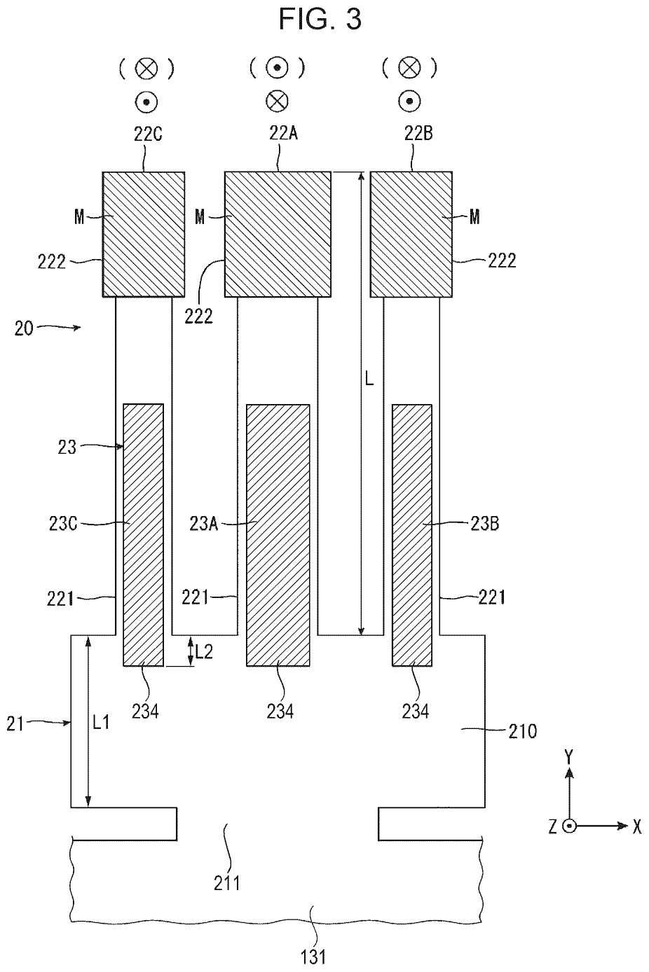

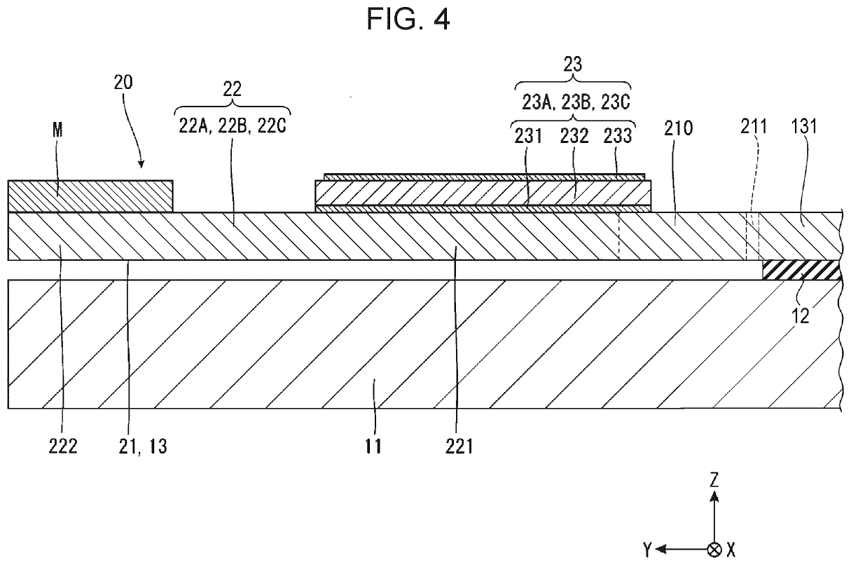

The vibration substrate 21 has a plate shape, and has an upper surface and a lower surface opposed to each other. Further, as illustrated in FIG. 3, the vibration substrate 21 has a support portion 210, three vibrating arms 22 extending from the support portion 210, and a fixing portion 211 that fixes the support portion 210 to the base portion 131. As illustrated in FIG. 4, the base portion 131 is supported by the silicon layer 11 and the BOX layer 12 located below, whereas the BOX layer 12 is not present under the vibrating arms 22, the support portion 210, and the fixing portion 211, which are separated from the silicon layer 11. Therefore, the vibrating arms 22, the support portion 210, and the fixing portion 211 are fixed to the base portion 131 at the side surface of the fixing portion 211 on the base portion 131 side. The entire vibration substrate 21 is formed with the same thickness as the surface silicon layer 13.

As illustrated in FIG. 3, vibrating arms 22A, 22B, and 22C extend from the support portion 210 toward the positive side in the Y-axis direction, which is the first direction, and are arranged side by side at equal intervals in the X-axis direction, which is the second direction. More specifically, the vibrating arm 22A is positioned at the center of the arrangement, the vibrating arm 22B is positioned on the positive side of the vibrating arm 22A in the X-axis direction, and the vibrating arm 22C is positioned on the negative side of the vibrating arm 22A in the X-axis direction. Each of the vibrating arms 22A, 22B, and 22C includes an arm portion 221 extending from the support portion 210 to the positive side in the Y-axis direction, and a wide portion 222 which is disposed on the distal end side of the arm portion 221 and is wider than the arm portion 221. Hereinafter, for convenience of description, the lengths of the vibrating arms 22A, 22B, and 22C, and the support portion 210 along the Y-axis direction are referred to as “lengths”, and lengths along the X-axis direction are referred to as “widths”.

Each arm portion 221 is linear in shape and has a width constant in the Y-axis direction. The width of each wide portion 222 is larger than the width of the corresponding arm portion 221. Each wide portion 222 is linear in shape and has a width constant in the Y-axis direction. With such a configuration, the mass of the tip end portion of each of the vibrating arms 22A, 22B, and 22C increases due to a mass effect of the wide portion 222. Thus, if the resonance frequency of the resonator element 20 is the same, the whole length of each of the vibrating arms 22A, 22B, and 22C can be made shorter than that in a configuration without the wide portion 222, thereby reducing the resonator element 20 in size. Alternatively, if the whole length of each of the vibrating arms 22A, 22B, and 22C is the same, the resonance frequency of the resonator element 20 can be made lower than that in a configuration without the wide portion 222.

The resonator element 20 further includes a weight portion M in a film shape disposed on each of the upper surfaces of the wide portions 222 of the vibrating arms 22A, 22B, and 22C. By disposing the weight portions M, the masses of the wide portions 222 are increased, making the mass effect described above more remarkable. The constituent material of the weight portions M is not particularly limited, but preferably contains at least one material selected from aluminum (Al), titanium (Ti), chromium (Cr), gold (Au), silver (Ag), copper (Cu), and polysilicon (Si), for example. The term “aluminum (Al)” includes not only aluminum but also aluminum compounds such as aluminum oxide and aluminum nitride. The same applies to the other materials mentioned above. Although not illustrated, the weight portions M of the present embodiment have a configuration in which a surface layer of gold (Au) is stacked on a base layer of titanium (Ti). By using these materials, the weight portions M having a high specific gravity can be easily formed. However, the weight portions M are not essential.

As illustrated in FIG. 3, the resonator element 20 includes driving portions 23 that deform the vibrating arms 22A, 22B, and 22C in a flexural mode in the Z-axis direction. The driving portions 23 include a laminate 23A disposed on the upper surface of the vibrating arm 22A, a laminate 23B disposed on the upper surface of the vibrating arm 22B, and a laminate 23C disposed on the upper surface of the vibrating arm 22C. The laminates 23A, 23B, and 23C are shorter than the arm portions 221 and are disposed in regions corresponding to approximately the proximal halves of the vibrating arms 22A, 22B, and 22C. In addition, the laminates 23A, 23B, and 23C are shorter than the length L of the vibrating arms 22A, 22B, and 22C, and in the present embodiment, are disposed in regions corresponding to approximately the proximal halves of the vibrating arms 22A, 22B, and 22C. In addition, the laminates 23A, 23B, and 23C are disposed so as to extend from above the three vibrating arms 22 to above a part of the support portion 210. In order to balance the vibration, in the resonator element 20, at least the vibrating arms 22B and 22C located at both ends of the arrangement have the same configuration (shape and size), and the vibrating arm 22A at the center has a configuration (shape and size) different from that of the vibrating arms 22B and 22C as necessary.

Each of the laminates 23A, 23B, and 23C described above expands and contracts in the Y-axis direction by application of a drive voltage. When the laminates 23A, 23B, and 23C expand and contract in the Y-axis direction, the vibrating arms 22A, 22B, and 22C perform flexural vibration in the Z-axis direction.

The laminates 23A, 23B, and 23C, which are the driving portions 23, have the same configuration, and as illustrated in FIG. 4, each of them has a laminate including a first electrode 231, a piezoelectric layer 232 disposed on the upper surface of the first electrode 231, and a second electrode 233 disposed on the upper surface of the piezoelectric layer 232. The constituent material of each portion of the laminates 23A, 23B, and 23C is not particularly limited. For example, the piezoelectric layer 232 is made of aluminum nitride (AlN) or the like, and the first electrode 231 and the second electrode 233 are made of titanium nitride (TiN) or the like. However, the configurations of the laminates 23A, 23B, and 23C are not particularly limited, and another layer may be interposed between the layers in each laminate. Further, the first electrode 231 may be formed by utilizing the surface silicon layer 13. That is, the three vibrating arms 22 formed of the surface silicon layer 13 may also serve as the first electrodes 231, and the driving portions 23 disposed on the upper surfaces of the three vibrating arms 22 may include the laminates 23A, 23B, and 23C including at least piezoelectric layers and electrodes.

As illustrated in FIG. 3, wiring of the laminates 23A, 23B, and 23C described above is configured such that adjacent ones of the vibrating arms 22A, 22B, and 22C perform flexural vibration in mutually opposite phases. That is, the wiring of the laminates 23A, 23B, and 23C is configured such that a first state in which the vibrating arms 22B and 22C are deformed upward in a flexural mode and the vibrating arm 22A is deformed downward in a flexural mode and a second state in which the vibrating arms 22B and 22C are deformed downward in a flexural mode and the vibrating arm 22A is deformed upward in a flexural mode are alternately repeated. To be specific, the first electrodes 231 of the laminates 23B and 23C and the second electrode 233 of the laminate 23A are electrically coupled to the electrode pad PAD1 via wiring (not illustrated), and the second electrodes 233 of the laminates 23B and 23C and the first electrode 231 of the laminate 23A are electrically coupled to the electrode pad PAD2 via wiring (not illustrated). The coupling method is not limited to the above one, and various coupling methods are conceivable, such as coupling the first electrodes 231 of the laminates 23B and 23C to the electrode pad PAD1 and the electrode pad PAD2, respectively, with the first electrode 231 set at a floating potential.

Since adjacent ones of the vibrating arms 22A, 22B, and 22C perform flexural vibration in mutually opposite phases as described above, the vibrations of the vibrating arms 22A, 22B, and 22C are at least partly canceled. It is thus possible to effectively suppress vibration leakage from the resonator element 20. The flexural vibrations of the vibrating arms 22A, 22B, and 22C are greatly excited at the resonance frequency, and the impedance Z is minimized. As a result, by connecting the resonator device 1 to an oscillation circuit, an oscillator that oscillates at an oscillation frequency determined by the resonance frequency is obtained.

Next, the impedance Z of the resonator device 1 will be described in a case where the laminates 23A, 23B, and 23C are disposed so as to extend from above the vibrating arms 22 to above a part of the support portion 210 in a state where the vibrating arms 22 and the support portion 210 are separated from the silicon layer 11.

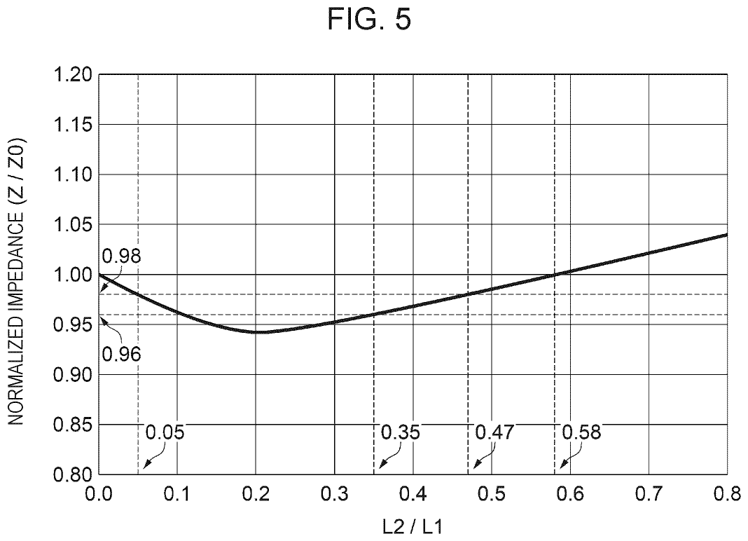

FIG. 5 shows the relationship between the normalized impedance (Z/Z0) and the ratio of the length L2 of overlapping portions 234 which are the portions of the laminates 23A, 23B, and 23C located on the support portion 210 to the length L1 of the support portion 210 in the first direction.

FIG. 5 is a graph illustrating a simulation result of the relationship between L2/L1 and the normalized impedance (Z/Z0). The normalized impedance (Z/Z0) on the vertical axis is obtained by normalizing the impedance Z when L2 is changed by using the impedance Z0 when L2 is 0. As illustrated in FIG. 5, the normalized impedance (Z/Z0) can be reduced to below 1.0 by setting L2/L1 to be greater than 0 and less than 0.58. That is, the impedance Z can be reduced to be a value smaller than or equal to the impedance Z0 when L2 is 0, which is the reference. In addition, the normalized impedance (Z/Z0) can preferably be reduced to 0.98 or less by setting L2/L1 to be 0.05 or more and 0.47 or less. Furthermore, the normalized impedance (Z/Z0) can more preferably be reduced to 0.96 or less by setting L2/L1 to be 0.1 or more and 0.35 or less.

Note that the length L1 of the support portion 210 satisfies 3%≤L1/L≤10%, where L is the length of the vibrating arms 22. In the case where L1/L<3%, the vibration of the vibrating arms 22 is transmitted to the base portion 131 fixed to the silicon layer 11 and the BOX layer 12 via the fixing portion 211, and the vibration is damped in the base portion 131. Therefore, it is difficult to achieve low impedance. In the case where 10%<L1/L, the entire length of the resonator element 20 increases, and it is difficult to downsize the resonator device 1. Therefore, when 3%≤L1/L≤10% is satisfied, it is possible to obtain the resonator device 1 which is small and can achieve low impedance.

This is because the support portion 210, together with the vibrating arms 22, is separated from the silicon layer 11, whereby the strain of the vibration of the vibrating arms 22 is generated in a part of the support portion 210. That is, the vibration of the vibrating arms 22 is transmitted in the range where 0<L2/L1<0.58. Thus, disposing the laminates 23A, 23B, and 23C so as to extend from above the vibrating arms 22 to above a part of the support portion 210 makes it possible to efficiently vibrate the vibrating arms 22. Therefore, the impedance Z can be reduced, and the minimum impedance can be achieved when L2/L1 is around 0.2.

In addition, if L2/L1 is in a range of 0.58<L2/L1, it is considered that the impedance Z increases on the contrary because such a range attempts to vibrate a region in which the strain due to the vibration of the vibrating arms 22 is not generated.

As described above, in the resonator device 1 of the present embodiment, since the lower portion of the support portion 210 is separated from the silicon layer 11 in the same manner as the vibrating arms 22, the vibration of the vibrating arms 22 is transmitted in the range where 0<L2/L1<0.58. Therefore, by arranging the laminates 23A, 23B, and 23C so as to extend from above the vibrating arms 22 to above a part of the support portion 210, in particular, in a range where 0<L2/L1<0.58, it is possible to efficiently vibrate the vibrating arms 22 and to achieve low impedance.

What is claimed is:

1. A resonator element comprising:
a vibration substrate including
a support portion, and
three or more vibrating arms extending from the support portion along a first direction and arranged side by side along a second direction orthogonal to the first direction; and
driving portions each disposed so as to extend over the support portion and the corresponding vibrating arm and configured to expand and contract in the first direction to cause the corresponding vibrating arm to perform flexural vibration in a third direction orthogonal to the first direction and the second direction, wherein
each driving portion is formed of
a laminate including a first electrode, a piezoelectric layer, and a second electrode stacked in this order on the corresponding vibrating arm.

2. The resonator element according to claim 1, wherein
0<L2/L1<0.58 holds,
where L1 is a length of the support portion along the first direction, and
L2 is a length of a portion of each laminate along the first direction, the portion being located on the support portion.

3. The resonator element according to claim 2, wherein
0.05≤L2/L1≤0.47 holds.

4. The resonator element according to claim 3, wherein
0.1≤L2/L1≤0.35 holds.

5. The resonator element according to claim 2, wherein
3%≤L1/L≤10% holds,
where L is a length of the vibrating arms along the first direction.

6. A resonator device comprising:
a multilayer substrate in which a device layer, a BOX layer, and a handle layer are stacked in this order,
the device layer including
the resonator element according to claim 1, and
a frame-shaped base portion that surrounds the resonator element and to which the support portion is fixed with a fixing portion interposed therebetween; and
a lid portion joined to the multilayer substrate and having a recessed portion on the multilayer substrate side, wherein
the resonator element is hermetically sealed in a space between the recessed portion and the multilayer substrate.

7. The resonator device according to claim 6, wherein
the multilayer substrate is an SOI substrate in which the device layer and the handle layer are made of silicon.

8. The resonator device according to claim 7, wherein the lid portion is made of silicon.

9. The resonator device according to claim 8, further comprising
first and second electrode pads disposed on a surface of the frame-shaped base portion on the lid portion side, wherein
in a plan view, the vibrating arms are disposed between the first electrode pad and the second electrode pad.

10. The resonator device according to claim 9, wherein
the SOI substrate includes
first and second through electrodes extending through the SOI substrate from a surface on the lid portion side to a surface on a side opposite to the lid portion,
the first electrode pad is electrically coupled to the first through electrode, and
the second electrode pad is electrically coupled to the second through electrode.
